(19) United States
(12) Patent Application Publication
(10) Pub. No.: US 2007/0202649 A1
(43) Pub. Date: Aug. 30, 2007

(54) Semiconductor device and method of manufacturing the same

(75) Inventor: Naoki Yokoi, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: ELPIDA MEMORY, INC., Tokyo (JP)

(21) Appl. No.: 11/705,597

(22) Filed: Feb. 13, 2007

(30) Foreign Application Priority Data
Feb. 14, 2006 (JP) 2006-36791

(51) Int. Cl. H01L 21/336; H01L 21/8242; H01L 21/3205

(52) U.S. Cl. 438/270; 438/589; 438/271; 438/272; 438/253

(57) ABSTRACT

In order to produce a MOS transistor having a gate electrode on a slope, patterning is first performed for a lower-layer gate electrode film near a lower end of the slope. A space between the lower-layer gate electrode films is filled with a filler so that the filler has the same height as a primary surface of a substrate. After an upper-layer gate electrode film is deposited, patterning is performed for the gate electrode films.

This application claims priority to prior Japanese patent application JP2006-36791, the disclosure of which is incorporated herein by reference.

### BACKGROUND OF THE INVENTION

1. Field of the Invention

The present invention relates to a semiconductor device, and more particularly to a semiconductor device having a MOS transistor formed on a slope of a semiconductor substrate. The present invention also relates to a method of manufacturing such a semiconductor device.

2. Description of the Related Art

Recently, semiconductor devices have made remarkable progress. For example, integration of semiconductor elements in a dynamic random access memory (DRAM) has more than doubled approximately every 12 months to 18 months. In order to achieve higher integration of semiconductor elements, Metal-Oxide-Semiconductor (MOS) transistors have been reduced in size. The reduction of the size may cause performance of a MOS transistor to be degraded by a short channel effect. It has been considered as a countermeasure of the above problem that a gate electrode is formed on a slope provided on a surface of a silicon substrate. Such a structure can lengthen an actual gate length as compared to a line width of the gate electrode.

Semiconductor devices having a gate electrode formed on a slope of a semiconductor substrate are disclosed by the following patent documents. Patent Document 1 (Japanese laid-open patent publication No. 05-259399) discloses a transistor having a gate provided on a slope of a substrate and a source/drain provided on a bottom and a primary surface of the substrate. Patent Document 2 (Japanese laid-open patent publication No. 61-051974) discloses a MOS transistor formed on a slope of a substrate. Patent Document 3 (Japanese laid-open patent publication No. 58-145156) discloses a MOS transistor including an enhancement type MOS formed on a bottom of a substrate and a depletion type MOS formed on a slope of a substrate which are connected to each other.

However, a MOS transistor using a slope of a substrate has the following problems. As shown in FIG. 1A, in a case where an element is sufficiently large in size as compared to a film thickness of a gate electrode film 605, a film thickness of the gate electrode film 605 near upper ends (opening portion) of slopes 602 of a substrate 601 is substantially the same as that of the gate electrode film 605 near lower ends (bottom portion) of the slopes 602. In a case where a semiconductor device is reduced in size, as shown in FIG. 1B, a groove portion 603 formed between the slopes 602 has such a narrow width so as to be fully filled with a material of the gate electrode film 605. In such a case, the film thickness of the gate electrode film 605 near the upper ends of the slopes 602 becomes different from that of the gate electrode film 605 near the lower ends of the slopes 602. Accordingly, it is difficult to conduct patterning by a dry etching process. Further, the gate electrode film 605 has a higher aspect ratio near the lower ends of the slopes 602. Therefore, it is also difficult to perform a dry etching process upon forming via holes in an interlayer film.

### SUMMARY OF THE INVENTION

As described above, in a MOS transistor using a slope of a semiconductor substrate, a gate electrode film has different thicknesses between a portion near an upper end of the slope and a portion near a lower end of the slope following recent miniaturization in semiconductor elements. Therefore, it problematically becomes difficult to conduct patterning by dry etching.

In view of the above problem, it is an object of the present invention to provide a semiconductor device and a method of manufacturing a semiconductor device which facilitate patterning near a lower end of a slope.

In order to resolve the above problem, the present invention basically adopts the following technology. As a matter of course, the present invention covers applied technology in which various changes and modifications are made therein without departing from the spirit of the present invention.

A method of manufacturing a semiconductor device according to the present invention includes forming a groove having a slope in a silicon substrate, forming a gate insulating film and a first gate electrode film, and patterning the first gate electrode film in the groove near a lower end of the slope so as to form a gate electrode.

The method of manufacturing a semiconductor device according to the present invention may further include filling a space between the gate electrodes with a filler as a diffusion layer up to a height of a primary surface of the silicon substrate.

In the method of manufacturing a semiconductor device according to the present invention, the filler may be formed of one of epitaxial silicon, metal having a high melting point, alloy of metal having a high melting point, and polysilicon, or a stacked layer including at least one of epitaxial silicon, metal having a high melting point, alloy of metal having a high melting point, and polysilicon.

The method of manufacturing a semiconductor device according to the present invention may further include forming a second gate electrode film after the filling process and simultaneously patterning the second gate electrode film and a remaining portion of the first gate electrode film.

In the method of manufacturing a semiconductor device according to the present invention, the first gate electrode film may be made of polysilicon. The second gate electrode film may have a structure including at least tungsten, tungsten nitride, and polysilicon or a stacked structure including tungsten, tungsten nitride, and polysilicon.

In the method of manufacturing a semiconductor device according to the present invention, the first gate electrode film may be made of polysilicon. The second gate electrode film may have a single-layer structure of polysilicon or a stacked structure including tungsten silicide and polysilicon.

A semiconductor device according to the present invention is manufactured by the aforementioned method.

A semiconductor device according to the present invention has a MOS transistor including a semiconductor substrate having a groove with a slope, a gate electrode formed on the slope of the groove formed in the semiconductor substrate, a first diffusion layer formed on a primary surface of the semiconductor substrate near an upper end of the slope, and a second diffusion layer formed by a filler filled near a lower end of the slope up to a height of the primary surface of the semiconductor substrate.

In order to produce a MOS transistor having a gate electrode on a slope according to the present invention, patterning is first conducted for a lower-layer gate electrode film near a lower end of the slope. Further, a space between the lower layers is filled with a filler so that the filler has the same height as a primary surface of a substrate. After an upper-layer gate electrode film is deposited, patterning is conducted on the gate electrode films. Since the space between the gate electrodes has the same height as the primary surface of the substrate, a contact hole can be opened with a reduced aspect ratio.

As a first effect, it is possible to facilitate patterning of a gate electrode having different thicknesses on a slope by dry etching separately performed on an upper portion and a lower portion of the gate electrode. As a second effect, it is possible to prevent an aspect ratio of the gate electrode from being increased because a lower end of the slope is filled with a filler and to facilitate dry etching of a via hole. Thus, a gate length of a semiconductor device having a narrow gate line width can be increased, thereby making it possible to prevent degradation of transistor performance due to a short channel effect.

The above and other objects, features, and advantages of the present invention will be apparent from the following description when taken in conjunction with the accompanying drawings which illustrate preferred embodiments of the present invention by way of example.

### BRIEF DESCRIPTION OF THE DRAWINGS

FIGS. 1A and 1B are cross-sectional views showing the related art;

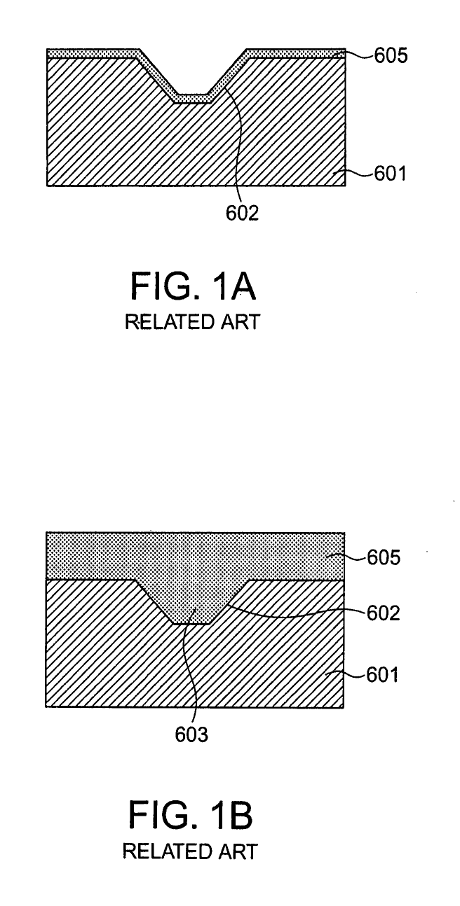

FIG. 2 is a cross-sectional view showing a memory cell portion of a DRAM according to an embodiment of the present invention;

FIGS. 3A to 3D are cross-sectional views showing processes in a manufacturing method according to an embodiment of the present invention;

FIGS. 4A to 4D are cross-sectional views showing processes in the manufacturing method according to the embodiment of the present invention; and

FIGS. 5A to 5D are cross-sectional views showing processes in the manufacturing method according to the embodiment of the present invention.

### DETAILED DESCRIPTION OF THE PREFERRED EMBODIMENTS

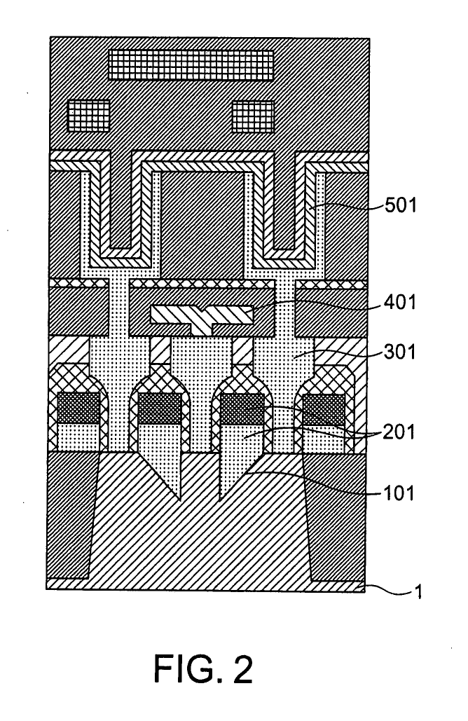

An embodiment of the present invention will be described below with reference to FIGS. 2 to 5D.

FIG. 2 is a cross-sectional view showing a memory cell portion of a dynamic random access memory (DRAM) according to an embodiment of the present invention. FIG. 2 shows memory cells of 2 bits, which are connected to a common bit line. As shown in FIG. 2, slopes 101 are formed in an active region of a silicon substrate 1. Gate electrodes 201 of MOS transistors are provided on the slopes 101 with a gate insulating film formed between the slopes 101 and the gate electrodes 201. The gate insulating film is so thin that it is not illustrated in FIG. 2. With the gate electrodes 201 having the above arrangement, channel portions are formed on the slopes. Accordingly, it is possible to make a channel length of the transistor larger than the width of the gate electrode 201. Consequently, even if the device is reduced in size, it is possible to prevent degradation in characteristics of the transistors due to a short channel effect.

A space between the gate electrodes 201 near lower ends of the slopes 101 is filled with a filler such that the filler has a surface located at the same height as a surface of the semiconductor substrate. Diffusion layers of the MOS transistors formed on the slopes 101 are connected by a contact plug 301. A common diffusion layer located at a central portion is connected to a bit line 401. Diffusion layers located on both sides thereof are connected to respective memory cell capacitors 501. With use of the MOS transistors formed on the slopes 101, it is possible to prevent degradation in characteristics of the transistors due to a short channel effect and also reduce an area of the memory cells. As a result, it is possible to obtain a DRAM having a large capacity.

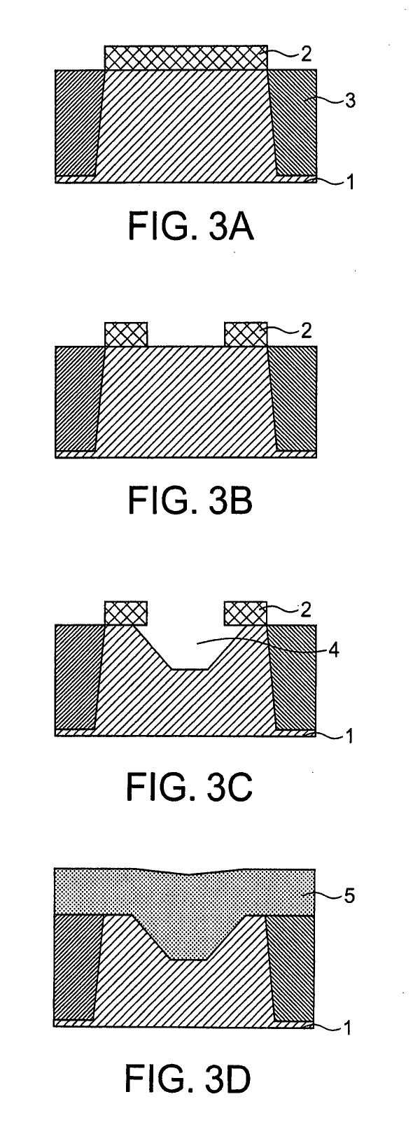

Next, a method of manufacturing a semiconductor device according to an embodiment of the present invention will be described with reference to FIGS. 3A to 5D.

First, as shown in FIG. 3A, after a thermal oxide film having a thickness of about 10 nm is formed on a silicon substrate 1 having a (001) crystal axis in the same manner as in the prior art, a first silicon nitride film 2 is deposited on the thermal oxide film by chemical vapor deposition (CVD) so as to have a thickness of about 100 nm. The thermal oxide film is so thin that it is not illustrated in the drawings. Then, the first silicon nitride film 2 is patterned with a mask of a photoresist by dry etching. Thereafter, the silicon substrate 1 is etched with a mask of the first silicon nitride film 2 by dry etching so as to form openings having a depth of about 250 nm in the silicon substrate 1. Subsequently, a silicon oxide film 3 is embedded into the openings by CVD. Then, an excessive silicon oxide film is removed by chemical mechanical polishing (CMP) and wet etching to thereby form shallow trench isolation (STI).

Next, as shown in FIG. 3B, the first silicon nitride film 2 is etched with a mask of a photoresist by dry etching so as to form a pattern for a groove in an active region. Thereafter, the photoresist is removed.

Subsequently, as shown in FIG. 3C, the silicon substrate 1 is etched with a mask of the first silicon nitride film 2 by wet etching using an alkali liquid such as ammonia water so as to form a groove 4 in the active region. The groove 4 has an inversed trapezoidal shape with a depth of about 100 nm. The groove 4 includes side surfaces (slopes) having a (111) crystal axis of silicon and a bottom having a (001) crystal axis of silicon.

Then, as shown in FIG. 3D, the silicon nitride film 2 and the thermal oxide film are removed. Thermal oxidation is performed on a surface of the silicon substrate 1 so as to form a thermal oxide film having a thickness of about 6 nm. The thermal oxide film serves as a gate insulating film and is so thin that it is not illustrated in FIG. 3D. Further, a first polysilicon film 5 is deposited on the thermal oxide film by CVD so as to have a thickness of about 140 nm. The first polysilicon film 5 serves as a first gate electrode film, which forms a lower layer of gate electrodes.

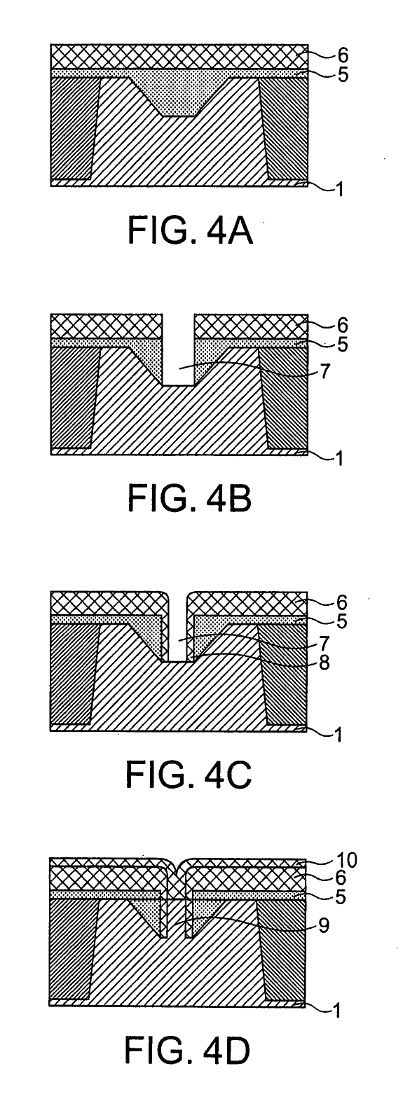

Subsequently, as shown in FIG. 4A, the first polysilicon film 5 is flattened by CMP. Thereafter, a second silicon nitride film 6 is deposited on the first polysilicon film 5 by CVD so as to have a thickness of about 50 nm.

Next, as shown FIG. 4B, the second silicon nitride film 6 is patterned with a mask of a photoresist by dry etching, and then the photoresist is removed. Further, the first polysilicon film 5 is etched with a mask of the second silicon nitride film 6 by dry etching so as to form an opening 7, which reaches the silicon substrate 1. Through this dry etching, the polysilicon film 5 is etched near lower ends of the slopes of the groove 4, so that one of edges of each gate electrode is patterned.

After a third silicon nitride film is deposited thereon, as shown in FIG. 4C, an etch-back process is performed through dry etching so that sidewalls 8 of the silicon nitride film are formed on side surfaces of the opening 7. The sidewalls 8 have a thickness of 10 nm to 20 nm.

Subsequently, as shown in FIG. 4D, silicon as a filler is epitaxially grown selectively from a bottom of the opening 7 so as to form an epitaxial layer 9. The epitaxial layer 9 has an upper end located at substantially the same height as the surface of the silicon substrate 1. Since the epitaxial layer 9 serves as a diffusion layer of a transistor, an impurity may be introduced into the epitaxial layer 9 during the epitaxial growth in order to provide a diffusion layer. Thus, the opening 7 is embedded with the epitaxial layer 9 as a filler, so that a step height is eliminated. Further, a fourth silicon nitride film 10 having a thickness of about 40 nm is deposited so that a surface of the epitaxially grown silicon is covered with the silicon nitride film 10.

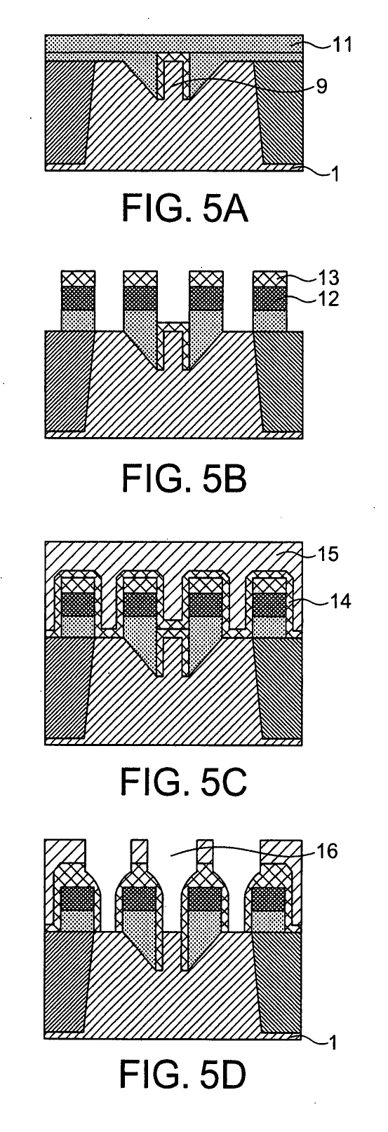

Next, as shown in FIG. 5A, an excessive silicon nitride film on its upper surface is removed so that the silicon nitride film remains only above the upper end of the epitaxial layer 9. Thereafter, a second polysilicon film 11 is deposited by CVD so as to have a thickness of 30 nm to 70 nm.

Subsequently, as shown in FIG. 5B, a metal layer 12 made of tungsten and tungsten nitride is deposited on the second polysilicon film 11 by sputtering or the like so as to have a thickness of 50 nm to 60 nm. The second polysilicon film 11 and the metal layer 12 of tungsten and tungsten nitride form an upper layer of the gate electrodes. Further, a hard mask layer 13 including a silicon nitride film is deposited by CVD or the like so as to have a thickness of 100 nm to 150 nm. The hard mask layer 13 is etched with a mask of a photoresist by dry etching. After the photoresist is removed, the metal layer 12 of tungsten and tungsten, the second polysilicon film 11, and the first polysilicon film are etched with a mask of the hard mask layer 13 by dry etching. Through this dry etching, gate electrodes are patterned.

Next, as shown in FIG. 5C, a fifth silicon nitride film 14 is deposited so as to have a thickness of 5 nm to 20 nm. Then, an interlayer film 15 including a silicon oxide film is deposited so as to have a thickness of 500 nm to 70 nm. Thereafter, a surface of the interlayer film 15 is flattened by CMP.

Subsequently, as shown in FIG. 5D, the interlayer film 15 is etched with a mask of a photoresist by dry etching so as to form openings 16. After the photoresist is removed, the silicon nitride film located at bottoms of the openings 16 is etched by dry etching so that the openings 16 serve as via holes, which reach the silicon substrate 1. As described above, the portion near the lower ends of the slopes of the groove is embedded with the filler so as to have the same height as the primary surface of the silicon substrate 1. Accordingly, the openings 16 have the same aspect ratio after etching. Thus, it is possible to conduct patterning and etching of a fine pattern.

Finally, contact plugs, capacitors, and metal interconnections are formed in the same manner as in the prior art. Thus, it is possible to produce a DRAM memory cell as shown in FIG. 2.

In the above embodiment, the gate electrode has a stacked structure including tungsten, tungsten nitride, and polysilicon. However, a stacked structure including tungsten silicide and polysilicon or a single-layer structure of polysilicon may be applied to the gate electrode. Further, the polysilicon layer may include impurities. For example, an impurity may be introduced into the polysilicon layer in a vapor phase at the time of the deposition of the polysilicon layer by CVD. Alternatively, an impurity may be introduced into the polysilicon layer by ion implantation after the deposition of the polysilicon layer. The opening 7 is embedded with the epitaxial layer up to the height of the primary surface of the silicon substrate. However, a compound layer including at least one of metal having a high melting point, alloy of metal having a high melting point, polysilicon, and an epitaxial layer may be used instead of the epitaxial layer in the above example. The filler is not limited to a specific material as long as it can serve as a diffusion layer and embed the opening 7 up to the height of the primary surface of the silicon substrate.

According to the present embodiment, in order to form a gate electrode of a transistor on a slope of a silicon substrate, a dry etching is performed separately on an upper portion and a lower portion of the gate electrode having different thicknesses on the slope. Therefore, it is possible to facilitate patterning of the gate electrode by dry etching. Further, an epitaxial layer of silicon is formed at a lower end of the slope. Consequently, it is possible to prevent an aspect ratio of the gate electrode from being increased at the lower end of the slope and facilitate opening of a via hole. According to the present invention, it is possible to prevent degradation in characteristics of a transistor due to a short channel effect and also reduce an area of a memory cell. As a result, a highly integrated semiconductor device can be obtained.

Although a preferred embodiment of the present invention has been described in detail, the present invention is not limited to the illustrated embodiment. Various changes and combinations can be applied to the present invention. Many modifications and variations may be made therein without departing from the scope of the present invention and are thus included in the scope of the present invention.

1. A method of manufacturing a semiconductor device having a silicon substrate, the method comprising:
forming a groove having a slope in the silicon substrate;
forming a gate insulating film and a first gate electrode film; and
patterning the first gate electrode film in the groove near a lower end of the slope to form a first gate electrode.

2. The method according to claim 1, further comprising:
filling a space between the first gate electrodes with a filler serving as a diffusion layer up to a height of a primary surface of the silicon substrate.

3. The method according to claim 2, wherein:
the filler is formed of any one of epitaxial silicon, metal having a high melting point, alloy of metal having a high melting point, and polysilicon, or a stacked layer including at least one of epitaxial silicon, metal having a high melting point, alloy of metal having a high melting point, and polysilicon.

4. The method according to claim 2, further comprising:
forming a second gate electrode film after the filling step; and
simultaneously patterning the second gate electrode film and a remaining portion of the first gate electrode film.

5. The method according to claim 4, wherein:
the first gate electrode film is made of polysilicon, and
the second gate electrode film has a structure including at least tungsten, tungsten nitride, and polysilicon or a stacked structure including tungsten, tungsten nitride, and polysilicon.

6. The method according to claim 4, wherein:
the first gate electrode film is made of polysilicon, and
the second gate electrode film has a single-layer structure of polysilicon or a stacked structure including tungsten silicide and polysilicon.

7. A semiconductor device manufactured by the method according to claim 1.

8. A semiconductor device comprising a MOS transistor including:
a semiconductor substrate having a groove with a slope;
a gate electrode formed on the slope of the groove;
a first diffusion layer formed on a primary surface of the semiconductor substrate near an upper end of the slope; and
a second diffusion layer formed by a filler filled near a lower end of the slope up to a height of the primary surface of the semiconductor substrate.

9. A semiconductor device manufactured by the method according to claim 2.

10. A semiconductor device manufactured by the method according to claim 3.

11. A semiconductor device manufactured by the method according to claim 4.

12. A semiconductor device manufactured by the method according to claim 5.

13. A semiconductor device manufactured by the method according to claim 6.
